(19) United States
(12) Patent Application Publication
(10) Pub. No.: US 2016/0188772 A1
(43) Pub. Date: Jun. 30, 2016

(54) METHOD OF DESIGNING AN INTEGRATED CIRCUIT AND COMPUTING SYSTEM FOR DESIGNING AN INTEGRATED CIRCUIT

(71) Applicant: Samsung Electronics Co., Ltd., Suwon-si (KR)

(72) Inventors: Jun-Ho Seo, Suwon-si (KR); Taek-Kyun Shin, Gwangmyeong-si (KR)

(21) Appl. No.: 14/805,606

(22) Filed: Jul. 22, 2015

(30) Foreign Application Priority Data
Dec. 30, 2014 (KR) 10-2014-0193019

(51) Int. Cl. G06F 17/50; G01R 31/317; G01R 31/3177

(52) U.S. Cl. CPC G06F 17/5022; G01R 31/3177; G01R 31/31723; G06F 17/5081

(57) ABSTRACT

In a method of and computing system for designing or modifying a design of an integrated circuit including a combinational logic and a scan chain, at least one flip-flop satisfying a predetermined condition is detected from among a plurality of flip-flops included in the scan chain by analyzing the combinational logic, and the detected flip-flop is replaced with a settable flip-flop that is set during a scan test for the integrated circuit, a resettable flip-flop that is reset during the scan test, or a settable-and-resettable flip-flop that is set or reset during the scan test.

### CROSS-REFERENCE TO RELATED APPLICATIONS

This U.S. non-provisional application claims the benefit of priority under 35 U.S.C. §119 to Korean Patent Application No. 10-2014-0193019 filed on Dec. 30, 2014 in the Korean Intellectual Property Office (KIPO), the entire contents of which are incorporated by reference herein in its entirety.

### BACKGROUND

In designing an integrated circuit, such as a system-on-chip (SoC), sequential circuits of the integrated circuit may be designed as a scan chain including a plurality of flip-flops that are connected in series to improve a testability of the integrated circuit. To perform a scan test for the integrated circuit, a shift-in operation is performed to sequentially load a test pattern into the integrated circuit, a capture operation is performed to store result values of an associated combinational logic based on the loaded test pattern, and a shift-out operation is performed to sequentially output the results values stored in the scan chain.

During a scan test of a conventional integrated circuit, the flip-flops may simultaneously toggle according to the test pattern and, thus, a peak current greater than a desirable or tolerable current level may occur. A path delay, clock skew, performance degradation, and so on may be caused by the peak current, which results in a scan test failure. That is, when a number of flip-flops simultaneously toggle during a capture operation of the scan test, a dynamic voltage drop may be caused by the peak current, and thus erroneous values may be output from the scan test. Further, outputs of analog circuits or memory blocks are not well controlled, and thus testability and test coverage of the scan test may be reduced.

### SUMMARY

In accordance with aspects of the inventive concept, provided is a method of designing or modifying a design of an integrated circuit that is capable of reducing a peak current during a scan test for the integrated circuit and/or increasing a test coverage of the integrated circuit.

In accordance with other aspects of the inventive concept, provided is a computing system for designing or modifying a design of an integrated circuit that is capable of reducing a peak current during a scan test for the integrated circuit and/or increasing a test coverage of the integrated circuit.

According to an aspect of the inventive concept, there is provided a method of designing or modifying a design of an integrated circuit including a combinational logic and a scan chain, in which a flip-flop satisfying a predetermined condition is detected from among a plurality of flip-flops included in the scan chain by analyzing the combinational logic, and the detected flip-flop is replaced with one of a settable flip-flop that is set during a scan test for the integrated circuit, a resettable flip-flop that is reset during the scan test, and/or a settable-and-resettable flip-flop that is set or reset during the scan test.

In various embodiments, the flip-flop satisfying the predetermined condition may include a flip-flop coupled to an input of a logic cone having a logic depth greater than a first predetermined value, a flip-flop having a number of fan-outs that is greater than a second predetermined value, or a flip-flop coupled to an output of a multiplexer.

In various embodiments, the settable flip-flop may be set during a capture operation of the scan test, the resettable flip-flop may be reset during a capture operation of the scan test, and the settable-and-resettable flip-flop may be set or reset during a capture operation of the scan test.

In various embodiments, to detect a flip-flop satisfying the predetermined condition, at least one logic cone having a logic depth greater than a predetermined value may be detected from among a plurality of logic cones included in the combinational logic by analyzing the plurality of logic cones included in the combinational logic, and a flip-flop coupled to an input of the detected logic cone may be detected as the flip-flop satisfying the predetermined condition.

In various embodiments, in replacing the detected flip-flop with the settable flip-flop, the resettable flip-flop, or the settable-and-resettable flip-flop, the flip-flop coupled to the input of the detected logic cone may be replaced with the resettable flip-flop when the detected logic cone is an AND-type logic cone.

In various embodiments, in replacing the detected flip-flop with the settable flip-flop, the resettable flip-flop, or the settable-and-resettable flip-flop, the flip-flop coupled to the input of the detected logic cone may be replaced with the settable flip-flop when the detected logic cone is an OR-type logic cone.

In various embodiments, in replacing the detected flip-flop with the settable flip-flop, the resettable flip-flop, or the settable-and-resettable flip-flop, the flip-flop coupled to the input of the detected logic cone may be replaced with the settable-and-resettable flip-flop.

In various embodiments, to detect the flip-flop satisfying the predetermined condition, at least one flip-flop having a number of fan-outs that is greater than a predetermined value may be detected from among the plurality of flip-flops included in the scan chain.

In various embodiments, to detect the flip-flop satisfying the predetermined condition, a flip-flop coupled to an output of a multiplexer may be detected from among the plurality of flip-flops included in the scan chain.

In various embodiments, an OR gate that performs an OR operation on an output of the detected flip-flop and a set signal may be added to replace the detected flip-flop with the settable flip-flop.

In various embodiments, a NOR gate that performs a NOR operation on an output of the detected flip-flop and a reset signal may be added to replace the detected flip-flop with the resettable flip-flop.

In various embodiments, an OR gate that performs an OR operation on an output of the detected flip-flop and a set signal, and a NOR gate that performs a NOR operation on an output of the OR gate and a reset signal may be added to replace the detected flip-flop with the settable-and-resettable flip-flop.

In various embodiments, a number of flip-flops simultaneously toggling during a capture operation of the scan test may be detected from among the plurality of flip-flops by performing a scan simulation on the integrated circuit including the replaced flip-flop. When the number of the flip-flops substantially simultaneously toggling is greater than a predetermined value, the steps of detecting and replacing may be re-performed based on a relaxed, e.g., lesser, predetermined condition.

In various embodiments, a power consumed during a capture operation of the scan test may be estimated by performing a scan simulation and a power estimation on the integrated circuit including the replaced flip-flop. When the estimated power is greater than a predetermined value, the steps of detecting and replacing may be re-performed based on a relaxed, e.g., lesser, predetermined condition.

According to another aspect of the inventive concept, there is provided a computing system configured to design or modify a design of an integrated circuit including a combinational logic and a scan chain that includes a memory device into which a design tool for the integrated circuit is loaded, and a processor configured to execute the design tool loaded into the memory device. The design tool executed by the processor detects a flip-flop satisfying a predetermined condition from among a plurality of flip-flops included in the scan chain by analyzing the combinational logic, and replaces the detected flip-flop with a settable flip-flop that is set during a scan test for the integrated circuit, a resettable flip-flop that is reset during the scan test, or a settable-and-resettable flip-flop that is set or reset during the scan test.

According to another aspect of the inventive concept, there is provided a method of designing or modifying a design of an integrated circuit including a combinational logic divided into regions and a scan chain, including performing an analysis of one of the regions of the combinational logic to determine characteristics of the one region; detecting a flip-flop satisfying a predetermined condition from among a plurality of flip-flops included in the scan chain based on the analysis of the one region of the combinational logic; and replacing the detected flip-flop with one of a settable flip-flop that is set during a scan test for the integrated circuit, a resettable flip-flop that is reset during the scan test, and a settable-and-resettable flip-flop that is set or reset during the scan test.

In various embodiments, performing an analysis on the one region of the combinational logic includes at least one of determining a logic depth of a logic cone of the combinational logic, performing a scan simulation to determine a number of flip-flops of the scan chain that substantially simultaneously toggle during a capture operation and/or performing a power estimation to determine an amount of power consumed during the capture operation.

In various embodiments, the flip-flop satisfying the predetermined condition includes a flip-flop coupled to an input of a logic cone having a logic depth greater than a first predetermined value, a flip-flop having a number of fan-outs that is greater than a second predetermined value, or a flip-flop coupled to an output of a multiplexer.

In various embodiments, the settable flip-flop is set during a capture operation of the scan test, the resettable flip-flop is reset during a capture operation of the scan test and the settable-and-resettable flip-flop is set or reset during a capture operation of the scan test.

In various embodiments, detecting a flip-flop satisfying the predetermined condition includes detecting at least one logic cone having a logic depth greater than a predetermined value from among a plurality of logic cones included in the combinational logic by analyzing the plurality of logic cones included in the combinational logic; and detecting a flip-flop coupled to an input of the detected logic cone as the flip-flop satisfying the predetermined condition.

As described above, the method of designing or modifying a design of the integrated circuit and the computing system for designing the integrated circuit according to aspects of the inventive concept may replace at least one of the flip-flops included in a scan chain with a settable flip-flop, a resettable flip-flop or a settable-and-resettable flip-flop, thereby reducing a peak current during a scan test of the integrated circuit and/or increasing a test coverage of the scan test.

### BRIEF DESCRIPTION OF THE DRAWINGS

Exemplary embodiments of one or more new and useful process, machine, manufacture, and/or improvement thereof, in accordance with the inventive concept, are provided in the following detailed description taken in conjunction with the accompanying drawings, in which:

FIG. 1 is a flowchart illustrating an embodiment of a method of designing an integrated circuit, according to aspects of the inventive concept;

FIG. 2 is a schematic diagram illustrating an embodiment of a computing system configured to design an integrated circuit, according to aspects of the inventive concept;

FIG. 3 is a schematic block diagram illustrating an embodiment of an integrated circuit, according to aspects of the inventive concept;

FIG. 4 is a graph illustrating a number of flip-flops toggling during each capture operation of a scan test when the flip-flops are not replaced;

FIG. 5 is a flowchart illustrating an embodiment of a method of designing an integrated circuit, according to aspects of the inventive concept;

FIG. 6A is a diagram illustrating an embodiment of an AND-type logic cone;

FIG. 6B is a diagram illustrating an embodiment of a resettable flip-flop;

FIG. 7A is a diagram illustrating an embodiment of an OR-type logic cone;

FIG. 7B is a diagram illustrating an embodiment of a settable flip-flop;

FIG. 8 is a diagram illustrating an embodiment of a settable-and-resettable flip-flop;

FIG. 9 is a flowchart illustrating an embodiment of a method of designing an integrated circuit, according to aspects of the inventive concept;

FIG. 10 is a diagram illustrating an embodiment of a flip-flop having a number of fan-outs, that is greater than a predetermined value, according to aspects of the inventive concept;

FIG. 11 is a flowchart illustrating an embodiment of a method of designing an integrated circuit, according to aspects of the inventive concept;

FIG. 12 is a diagram illustrating an example of a flip-flop that is coupled to an output of a multiplexer;

FIG. 13 is a flowchart illustrating an embodiment of a method of designing an integrated circuit, according to aspects of the inventive concept;

FIG. 14 is a diagram illustrating a computing system configured to design an integrated circuit, according to aspects of the inventive concept;

FIG. 15 is a flowchart illustrating an embodiment of a method of designing an integrated circuit according to aspects of the inventive concept; and

FIG. 16 is a flowchart illustrating an embodiment of a method of performing a scan test for an integrated circuit, according to aspects of the inventive concept.

### DETAILED DESCRIPTION OF THE EMBODIMENTS

Aspects of the inventive concept will now be described more fully with reference to the accompanying drawings, in which exemplary embodiments are shown. The inventive concept may, however, be embodied in many different forms and should not be construed as limited to the exemplary embodiments set forth herein. Reference numerals are denoted in detail in the exemplary embodiments of the inventive concept and their examples are indicated in the accompanying drawings. The same reference numerals are used in the description and drawings in order to refer to the same or similar parts wherever possible.

It will be understood that, although the terms first, second, etc. may be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

To the extent that functional features, operations, and/or steps are described herein, or otherwise understood to be included within various embodiments of the inventive concept, such functional features, operations, and/or steps can be embodied in functional blocks, units, modules, operations and/or methods. And to the extent that such functional blocks, units, modules, operations and/or methods include computer program code, such computer program code can be stored in a computer readable medium, e.g., such as non-transitory memory and media, that is executable by at least one computer processor.

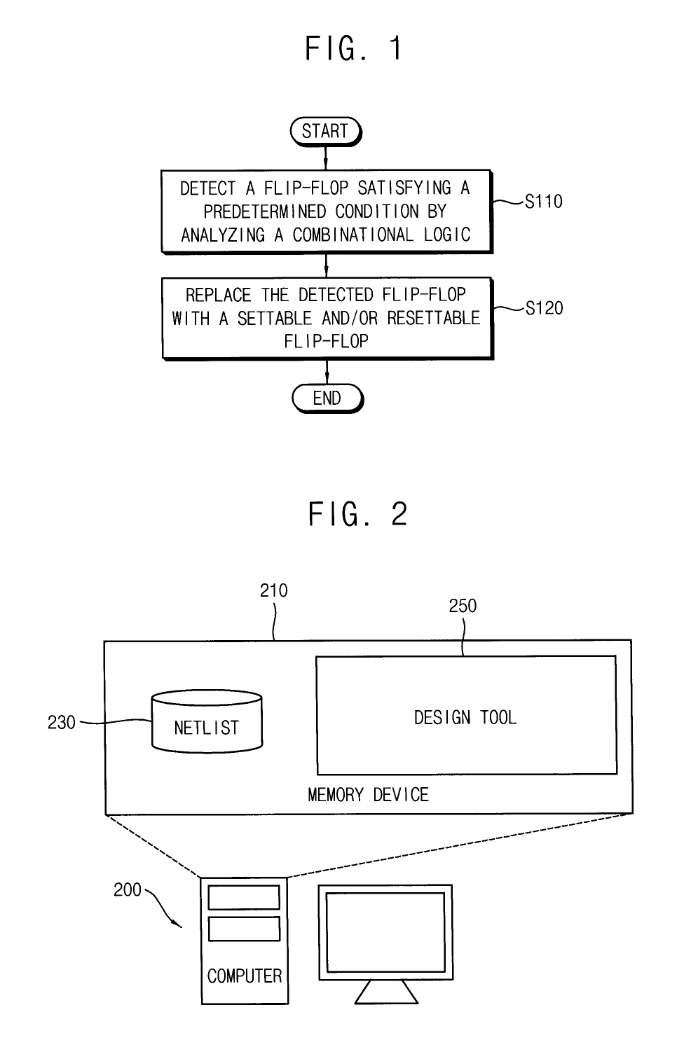

FIG. 1 is a flowchart illustrating an embodiment of a method of designing an integrated circuit, according to aspects of the inventive concept. FIG. 2 is a schematic diagram illustrating an embodiment of a computing system configured to design an integrated circuit, according to aspects of the inventive concept.

Referring to the embodiments of FIGS. 1 and 2, a computing system 200 for designing an integrated circuit (e.g., a system-on-chip (SoC)) includes at least one processor (not shown) and a memory device 210. The processor is configured to load into the memory device 210 a netlist 230 for the integrated circuit to be designed and a design tool 250 for the integrated circuit. The netlist 230 describes the connectivity of components in the design that are necessary for the circuit to properly function. The processor can be further configured to execute the design tool 250 loaded into the memory device 210.

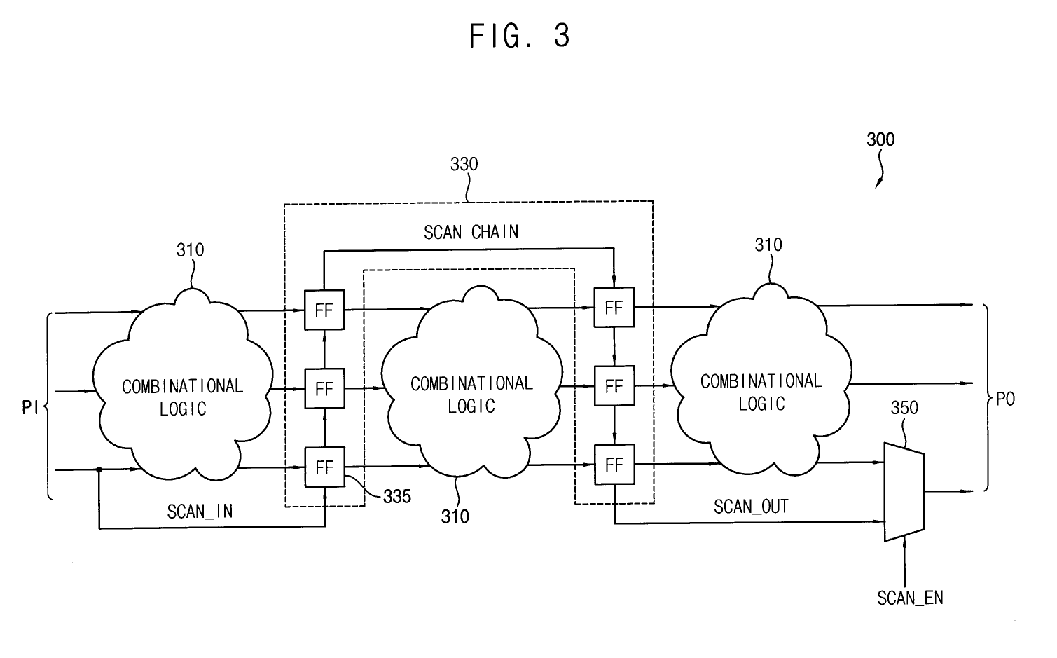

The netlist 230 loaded into the memory device 210 includes design information of the integrated circuit 300, see FIG. 3. For example, the netlist 230 may include connectivity information of components of the integrated circuit 300. As illustrated in FIG. 3, the integrated circuit 300 may be designed to include combinational logic 310 including a plurality of logic cones, a plurality of multiplexers, etc. (not shown), and a scan chain 330 including a plurality of flip-flops (FF) 335 that are connected in series as a design-for-test (DFT) circuit for facilitating an efficient test of the integrated circuit 300.

A scan test for the integrated circuit 300 is performed using this scan chain 330. For example, a shift-in operation may be performed to sequentially input a predetermined test pattern as a scan input SCAN_IN to the scan chain 330 through one or more of the primary inputs PI of the integrated circuit 300. Further, a capture operation may be performed such that the test pattern loaded into the scan chain 330 is provided to the combinational logic 310 to generate observed values based on the test pattern, and the observed values of the combinational logic 310 are stored in the scan chain 330.

In addition, a shift-out operation may be performed to sequentially output the observed values stored in the scan chain 330, as a scan output SCAN_OUT, through one or more of the primary outputs PO of the integrated circuit 300. In some example embodiments, a plurality of similar or different test patterns may be used. In one case, the shift-out operation that outputs the observed values for one test pattern and the shift-in operation that inputs the next test pattern may be performed substantially at the same time. In other cases, the shift-out operation that outputs the observed values for one test pattern and the shift-in operation that inputs the next test pattern may be performed at different times. For example, the shift-out operation could be performed before the shift-in operation of the next test pattern. Or, as another example, the shift-in operation of the next test pattern could be performed before the shift out operation.

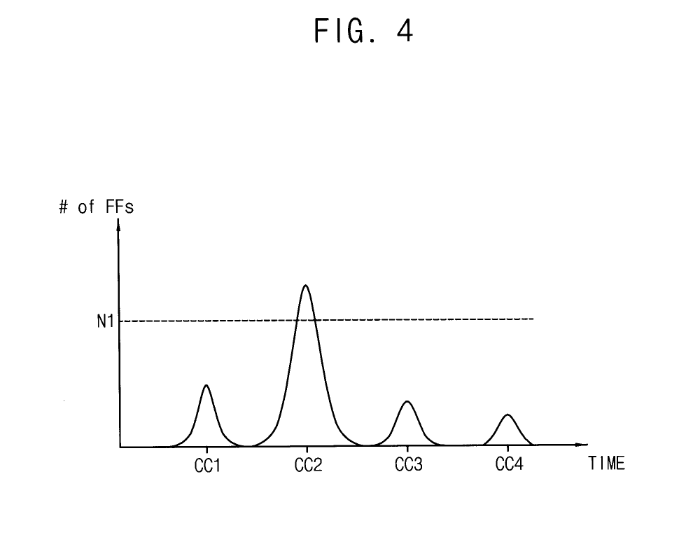

In a conventional integrated circuit, during this scan test, a number of flip-flops in the scan chain 330 may simultaneously toggle, and thus a peak current level may be greater than a predetermined level. Accordingly, path delay, clock skew and/or performance degradation may be caused by the peak current, which may result in a scan test failure. In particular, this peak current may occur during the capture operation of the scan test. For example, FIG. 4 illustrates a number of flip-flops that simultaneously, or substantially simultaneously, toggle during each of capture cycles CC1, CC2, CC3 and CC4. As shown, the number of flip-flops that simultaneously, or substantially simultaneously, toggle is greater than a predetermined value N1 during capture cycle CC2 of the capture cycles CC1, CC2, CC3 and CC4 of the capture operation, where N is a whole number that is less than or equal to the total number of flip-flops. In the case of capture cycle CC2, a peak current output from the scan chain may have a peak current level greater than a predetermined level, and a dynamic voltage drop may be caused by the peak current. This could cause erroneous observed values to be output as a result of the scan test. Although FIG. 4 illustrates an example where the capture operation for one test pattern is performed during a plurality of capture cycles CC1, CC2, CC3 and CC4, more generally, the capture operation for one test pattern may be performed during one or more capture cycles, in different embodiments.

Further, the integrated circuit 300, such as the SoC, may include circuit blocks (e.g., analog circuitry or one or more memory blocks) to which the test pattern is not applied. Since outputs of these blocks are generally not controlled, i.e., not directly subjected to testing applied during a scan test of the integrated circuit, a testability of the integrated circuit including these blocks may be reduced, and a test coverage of the scan test may be reduced.

In the computing system 200 of FIG. 2 for designing the integrated circuit according to aspects of the inventive concept, to reduce this peak current and/or to increase the test coverage, the design tool 250 executed by the processor may detect at least one flip-flop 335 satisfying a predetermined condition from among the plurality of flip-flops 335 included in the scan chain 330. This is done by analyzing the integrated circuit 300 or the combinational logic 310 included in the integrated circuit 300 (step S110, FIG. 1). For example, the at least one flip-flop 335 satisfying the predetermined condition may be a flip-flop causing a peak current during the capture operation, which may affect multiple logic cones (i.e., logic structures having multiple inputs processed through a number of logic stages to produce a single output or reduced number of outputs) included in the combinational logic 310, or a flip-flop coupled to an output or a logic cone that is not tightly controlled. More specifically, according to aspects of the inventive concept, for example, the at least one flip-flop 335 satisfying the predetermined condition may include a flip-flop coupled to an input of a logic cone having a logic depth greater than a first predetermined value, a flip-flop having a number of fan-outs that is greater than a second predetermined value, or a flip-flop coupled to an output of a multiplexer.

The design tool 250 executed by the processor may replace the detected flip-flop 335 with a new flip-flop, e.g., a settable flip-flop, a resettable flip-flop, or a settable-and-resettable flip-flop (step S120, FIG. 1). Accordingly, the netlist 230 for the integrated circuit 300 may be modified to include the new flip-flop. The new flip-flop (i.e., the settable flip-flop, the resettable flip-flop, or the settable-and-resettable flip-flop) may be set or reset during the capture operation of the scan test. As described above, since the original flip-flop satisfying the predetermined condition is replaced with the settable flip-flop, the resettable flip-flop or the settable-and-resettable flip-flop, the peak current during the capture operation may be reduced because the replaced flip-flop is controllable to not toggle during the capture operation. Further, the testability and the test coverage may be improved because the previously hardly-controlled output or logic cone now can be readily controlled using the replaced flip-flop coupled to the hardly-controlled output or logic cone.

In some example embodiments, the design tool 250 performing the detection (S110, FIG. 1) of the flip-flop 335 satisfying the predetermined condition and the replacement (S120) of the detected flip-flop 335 with the settable and/or resettable flip-flop may be implemented as a part of an electronic design automation (EDA) tool for designing the integrated circuit 300. In an example, the design tool 250 performing the detection and the replacement may implement a script of the EDA tool. In other example embodiments, the design tool 250 performing the detection and the replacement may be implemented as a separate tool from the EDA tool.

As described above, the method and the computing system 200 for designing the integrated circuit according to aspects of the inventive concept may replace at least one of the flip-flops included in the scan chain with the settable flip-flop, the resettable flip-flop or the settable-and-resettable flip-flop that is set or reset during the capture operation of the scan test, thereby reducing the peak current during the scan test for the integrated circuit and/or improving the test coverage of the scan test. Further, since the method and the computing system 200 for designing the integrated circuit according to aspects of the inventive concept can reduce the peak current and/or can improve the test coverage, the method and the computing system 200 can be readily employed in designing the integrated circuit that performs the scan test where scan compression is applied to reduce the number of test patterns input during the scan test.

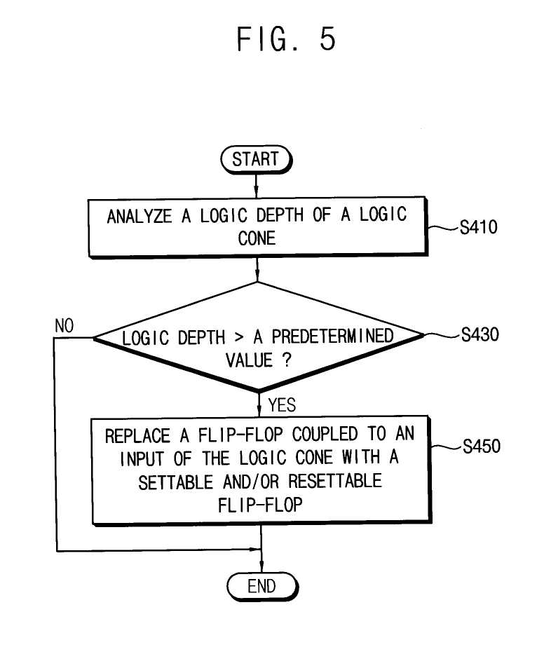

Referring to the embodiment of FIG. 5, in a method of designing an integrated circuit including a combinational logic 310 and a scan chain 330, a plurality of logic cones included in the combinational logic 310 may be analyzed to obtain logic depths, i.e., the number of logic stages between the inputs and output of the logic cones (step S410). For example, a static timing analysis (STA) for the integrated circuit may be performed to obtain the logic depths of the logic cones.

According to aspects of the inventive concept, a logic cone having a logic depth less than or equal to a predetermined value is excluded from the flip-flop replacement step of the method (step S430: NO result), and a logic cone having a logic depth greater than the predetermined value is included the flip-flop replacement step (step S430: YES result). Accordingly, a flip-flop coupled to an input of the included logic cone is detected as a flip-flop satisfying a predetermined condition.

As described herein, the flip-flop coupled to the input of the logic cone having the logic depth greater than the predetermined value is replaced with one of a settable flip-flop, a resettable flip-flop or a settable-and-resettable flip-flop (step S450).

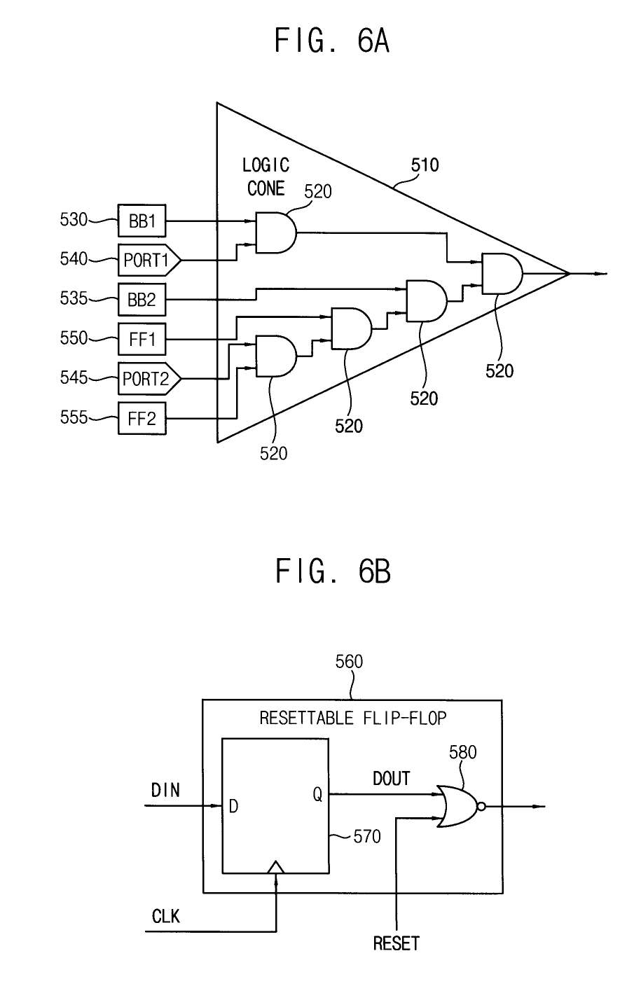

In some example embodiments according to aspects of the inventive concept, in a case where the included logic cone is an AND-type logic cone, a flip-flop coupled to an input of the AND-type logic cone is replaced with a resettable flip-flop. For example, as illustrated in the embodiments of FIGS. 6A and 6B, a logic cone 510 having a logic depth of 4 is shown, i.e., 4 levels of AND gates. The logic cone 510 may perform a logic operation on a plurality of inputs, for example, an input from at least one block BB1 530 and BB2 535 (e.g., an analog circuit or a memory block) that is processed as a “black box” (BB), an input from at least one port 540 and 545, and/or an input from at least one flip-flop 550 and 555 included in the scan chain 330. In an example, in a case where the logic cone analyzed in Step S410 in FIG. 5 is the AND-type logic cone 510 as illustrated in FIG. 6A, or in a case where the analyzed logic cone includes at least one AND gate 520 among other logic gate types, and the predetermined value of the logic depth applied in Step S430 in FIG. 5 is 3, at least one of the flip-flops 550 and 555 coupled to the inputs of the AND-type logic cone 510 are replaced with the resettable flip-flop 560 as illustrated in FIG. 6B.

For example, as illustrated in FIG. 6B, a NOR gate 580 is added to an output of the flip-flop 570 that stores input data DIN in response to a clock signal CLK and outputs the stored data as output data DOUT. The NOR gate 580 performs a NOR operation on the output of the flip-flop 570 and a reset signal RESET. Thus, when the reset signal RESET has a logic high level, the resettable flip-flop 560 including the NOR gate 580 outputs a signal having a logic low level, regardless of a logic level of the output data DOUT of the flip-flop 570. In some example embodiments, since at least one flip-flop 550 and 555 coupled to the input of the AND-type logic cone 510 is replaced with the resettable flip-flop 560, and the resettable flip-flop 560 is controllable to be reset during a capture operation of a scan test, the logic cone 510 can be readily controlled, and thus a test coverage of the scan test may be increased. This is because the potential for a peak current resulting from the scan test being greater than the predetermined current level which could cause the issues set forth above is reduced or eliminated, thus reducing or eliminating a scan test failure. Thus, in some example embodiments, since the resettable flip-flop 560 is controllable to not toggle during the capture operation, a peak current of the integrated circuit including the resettable flip-flop 560 and the logic cone 510 may be reduced during the capture operation.

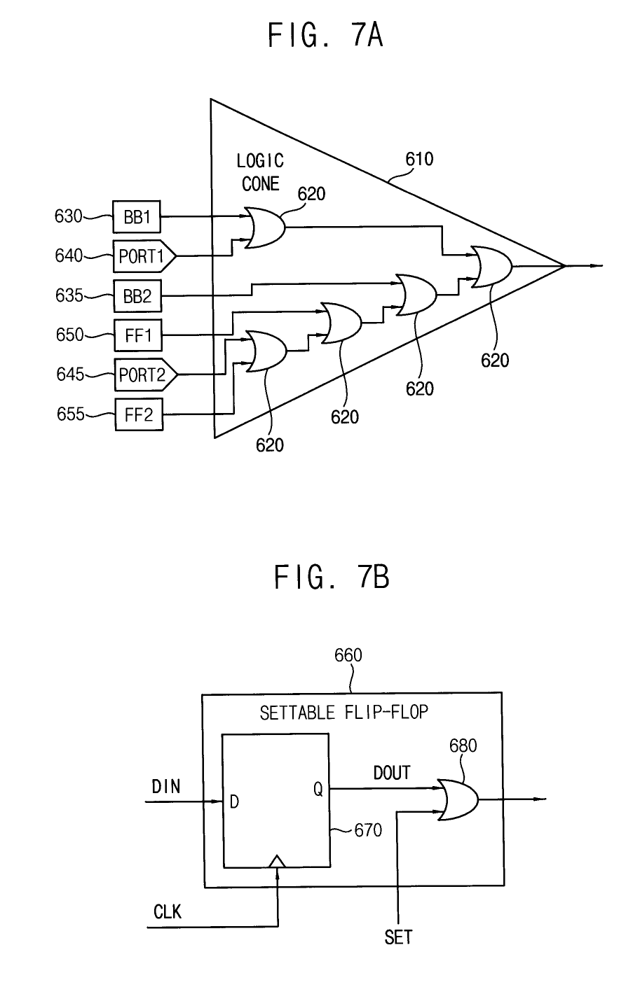

In other example embodiments according to aspects of the inventive concept, in a case where the detected logic cone is an OR-type logic cone, a flip-flop coupled to the input of the OR-type logic cone may be replaced with the settable flip-flop. For example, as illustrated in embodiment of FIGS. 7A and 7B, a logic cone 610 having a logic depth of 4 is shown, i.e., 4 levels of OR gates. The logic cone 610 may perform a logic operation on a plurality of inputs from at least one “black box” BB1 630 and BB2 635, at least one port 640 and 645, and/or at least one flip-flop 650 and 655. In an example, in a case where the logic cone 610 analyzed in Step S410 is the OR-type logic cone as illustrated in FIG. 7A, or in a case where the analyzed logic cone 610 includes at least one OR gate 620 among other logic gate types, and the predetermined value of the logic depth applied in Step S430 is 3, at least one of the flip-flops 650 and 655 coupled to the input of the OR-type logic cone 610 is replaced with a settable flip-flop 660 as illustrated in FIG. 7B.

For example, as illustrated in FIG. 7B, an OR gate 680 is added to an output of the flip-flop 670. The OR gate 680 performs an OR operation on the output of the flip-flop 670 and a set signal SET. Thus, when the set signal SET has a logic high level, the settable flip-flop 660 including the OR gate 680 outputs a signal having a logic high level regardless of a logic level of the output data DOUT of the flip-flop 670. In some example embodiments, since at least one flip-flop 650 and 655 coupled to the input of the OR-type logic cone 610 is replaced with the settable flip-flop 660, and the settable flip-flop 660 is controllable to be set during a capture operation of a scan test, the logic cone 610 can be readily controlled, and thus a test coverage of the scan test may be increased. This is because the potential for a peak current resulting from the scan test being greater than the predetermined current level which could cause the issues set forth above is reduced or eliminated, thus reducing or eliminating a scan test failure. Thus, in, in some example embodiments, since the settable flip-flop 660 is controllable to not toggle during the capture operation, a peak current of the integrated circuit including the settable flip-flop 660 and the logic cone 610 may be reduced during the capture operation.

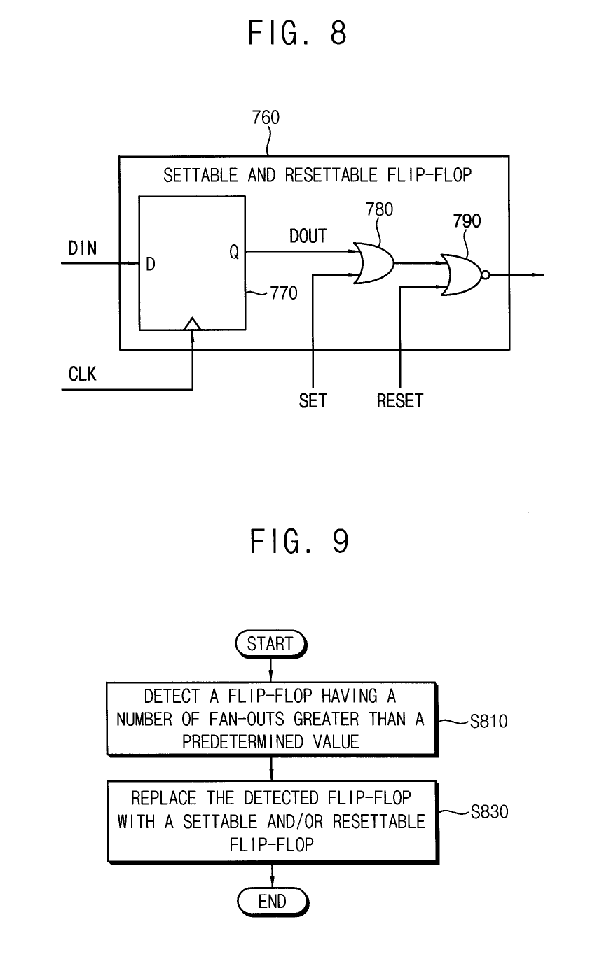

In still other example embodiments according to the inventive concept, a flip-flop coupled to the input of an analyzed logic cone may be replaced with the settable-and-resettable flip-flop. For example, as illustrated in the embodiment of FIG. 8, an OR gate 780 and a NOR gate 790 are added to an output of the flip-flop 770. The OR gate 780 performs an OR operation on the output of the flip-flop 770 and a set signal SET, and the NOR gate 790 performs a NOR operation on an output of the OR gate 780 and a reset signal RESET. Thus, the settable-and-resettable flip-flop 760 including the OR gate 780 and the NOR gate 790 outputs a signal having a logic high level regardless of a logic level of the output data DOUT of the flip-flop 770 when the set signal SET has a logic high level and the reset signal RESET has a logic low level, and outputs a signal having a logic low level regardless of the logic level of the output data DOUT of the flip-flop 770 when the set signal SET has a logic low level and the reset signal RESET has a logic high level. As described above, since the flip-flop 770 coupled to the input of the analyzed logic cone is replaced with the settable-and-resettable flip-flop 760, and the settable-and-resettable flip-flop 760 is set or reset during a capture operation of a scan test, the logic cone is readily controlled, and the test coverage of the scan test is increased, according to the inventive concept.

Although FIGS. 6A through 8 illustrate examples of the settable and/or resettable flip-flops, the settable and/or resettable flip-flops according to example embodiments are not limited thereto, and may be implemented in various manners to have various configurations.

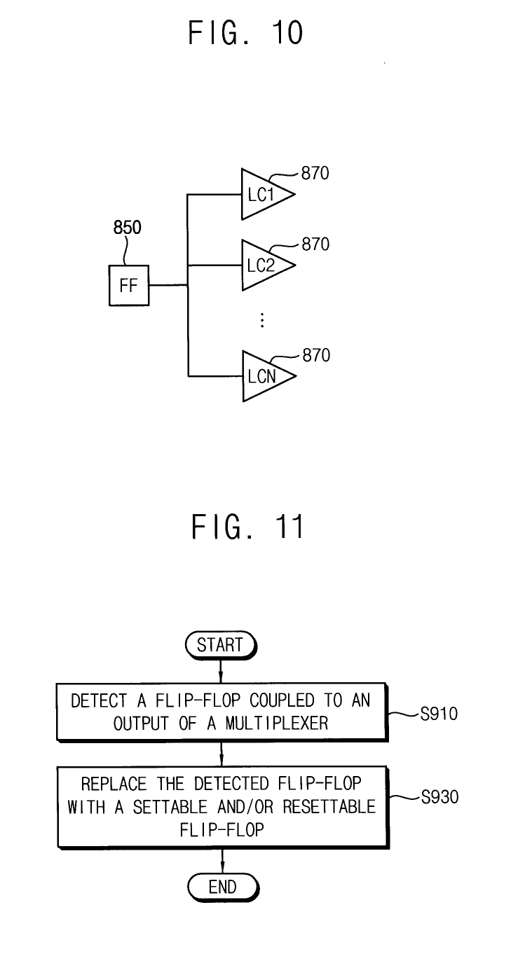

Referring to the embodiment of FIG. 9, in a method of designing an integrated circuit including a combinational logic 310 and a scan chain 330, at least one flip-flop having a number of fan-outs that is greater than a predetermined value is detected from among a plurality of flip-flops included in the scan chain (step S810), according to the inventive concept. For example, as illustrated in the embodiment of FIG. 10, a flip-flop 850 having an output coupled to inputs of a number N of logic cones (LC) 870, the number N being greater than the predetermined value (for example, N−1) is detected.

The flip-flop 850 having the number of N fan-outs, which is greater than the predetermined value N−1, is replaced with a settable flip-flop, a resettable flip-flop or a settable-and-resettable flip-flop (step S830), according to the inventive concept. For example, the flip-flop 850 may be replaced with the resettable flip-flop 560 illustrated in FIG. 6B, may be replaced with the settable flip-flop 660 illustrated in FIG. 7B, or may be replaced with the settable-and-resettable flip-flop 760 illustrated in FIG. 8. Thus, since the flip-flip 850 having a number N fan-outs, the number of which is greater than the predetermined value N−1 is replaced with the settable and/or resettable flip-flop, and is set or reset during a capture operation of a scan test for the integrated circuit, the flip-flip 850 is controllable to not toggle during the capture operation, thereby reducing a peak current of the integrated circuit including the flip-flip 850 and the logic cones 870 coupled thereto.

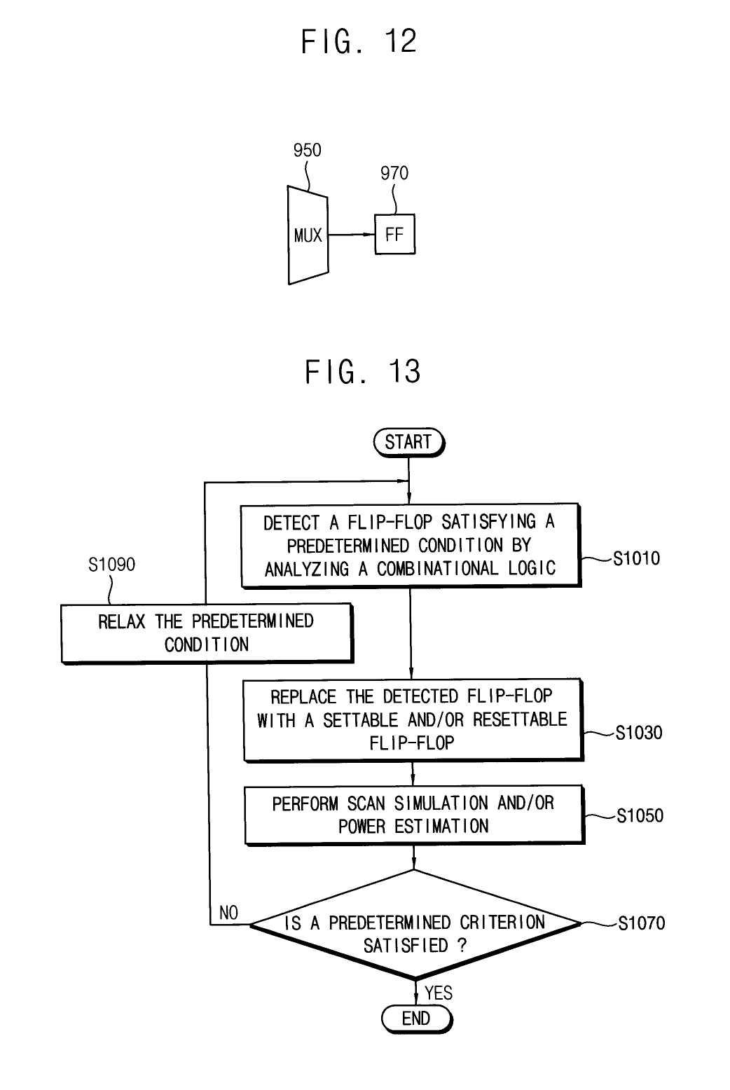

Referring to the embodiment of FIG. 11, in a method of designing an integrated circuit including a combinational logic and a scan chain, at least one flip-flop coupled to an output of a multiplexer included in the combinational logic 310 of an integrated circuit 300 is detected from among a plurality of flip-flops included in the scan chain 330 (step S910), according to of the inventive concept. As one example, as illustrated in the embodiment of FIG. 12, a flip-flip 970 coupled to an output of a multiplexer 950 is detected.

Accordingly, the flip-flip 970 coupled to the output of the multiplexer 950 is replaced with a settable flip-flop, a resettable flip-flop, or a settable-and-resettable flip-flop (step S930) according to of the inventive concept. For example, the flip-flip 970 may be replaced with the resettable flip-flop 560 illustrated in FIG. 6B, may be replaced with the settable flip-flop 660 illustrated in FIG. 7B, or may be replaced with the settable-and-resettable flip-flop 760 illustrated in FIG. 8. Thus, since the flip-flip 970 coupled to the output of the multiplexer 950 is replaced with the settable and/or resettable flip-flop 760, and is set or reset during a capture operation of a scan test for the integrated circuit, an output of the flip-flip 760 is controllable regardless of the output of the multiplexer 950, and thus a testability and a test coverage of a scan test is improved.

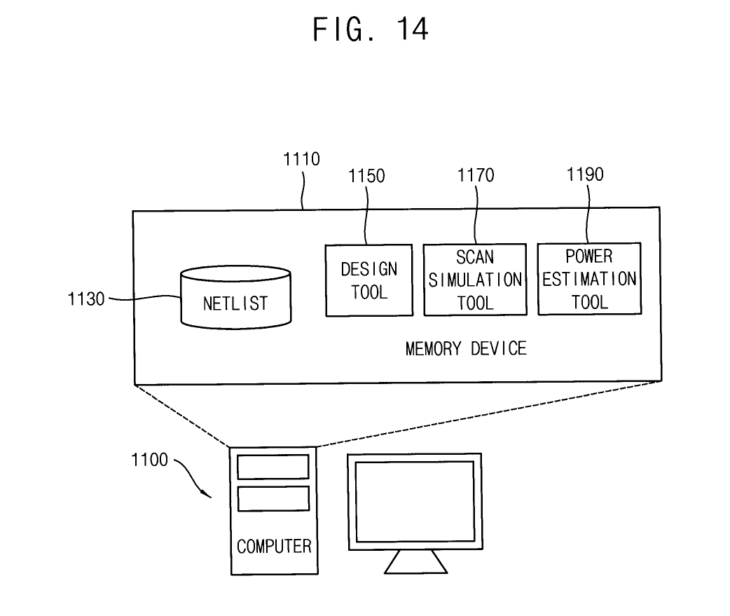

Referring to the embodiments of FIGS. 13 and 14, a computing system 1100 for designing an integrated circuit (e.g., a system-on-chip (SoC)) in accordance with the inventive concept includes a processor (not shown) and at least one memory device 1110. The processor is configured to load a netlist 1130 for the integrated circuit and a design tool 1150 for the integrated circuit into the memory device 1110. Further, the processor may load a scan simulation tool 1170 and/or a power estimation tool 1190 into the memory device 1110.

The processor executes the design tool 1150 loaded into the memory device 1110. The design tool 1150 executed by the processor detects at least one flip-flop satisfying a predetermined condition from among a plurality of flip-flops included in a scan chain of the integrated circuit by analyzing a combinational logic included in the integrated circuit represented by the netlist 1130 (step S1010). According to example embodiments, the design tool 1150 may detect a flip-flop related to a peak current during a capture operation of a scan test, and/or a flip-flop related to a test coverage of the scan test. For example, the design tool 1150 may detect a flip-flop coupled to an input of a logic cone having a logic depth greater than a first predetermined value, as illustrated in the example of FIG. 5, a flip-flop having a number of fan-outs greater than a second predetermined value as illustrated in FIG. 9, and/or a flip-flop coupled to an output of a multiplexer as illustrated in FIG. 11.

The design tool 1150 replaces the flip-flop satisfying the predetermined condition with a settable flip-flop, a resettable flip-flop, or a settable-and-resettable flip-flop (step S1030), according to of the inventive concept. Accordingly, the netlist 1130 for the integrated circuit is modified to include the replaced flip-flop. The replaced flip-flop may be set or reset during the capture operation of the scan test. Thus, since the flip-flop satisfying the predetermined condition is replaced with the settable and/or resettable flip-flop, and the settable and/or resettable flip-flop is set or reset during the capture operation of the scan test, the flip-flop is controllable to not toggle during the capture operation, which results in the reduction of the peak current, or the previously hardly-controlled output or logic cone is readily controlled as a result. This results in an increase in the testability and the test coverage during a scan test of an integrated circuit.

The processor may further execute a scan simulation tool 1170 and/or a power estimation tool 1190 to perform a scan simulation and/or a power estimation on the integrated circuit 300 including the replaced flip-flop (step S1050). In some example embodiments, the scan simulation tool 1170 is configured to perform the scan simulation on the integrated circuit including the replaced flip-flop to detect the number of flip-flops simultaneously toggling during the capture operation of the scan test from among the plurality of flip-flops included in the scan chain. If a result of the scan simulation satisfies a predetermined criterion (step S1070: YES result), for example, if the number of the flip-flops simultaneously toggling is less than or equal to a predetermined value, an additional flip-flop will not be replaced. However, if the result of the scan simulation does not satisfy a predetermined criterion (step S1070: NO result), for example, if the number of the flip-flops simultaneously toggling is greater than the predetermined value, the detection of the flip-flop not satisfying the predetermined condition is continued by relaxing the predetermined condition (steps S1090 and S1010), and the replacement of the detected flip-flop is again performed (step S1030). For example, the relaxing of the predetermined condition may include the detection of a flip-flop coupled to an input of a logic cone having a lower logic depth than the predetermined value used in the previous detection step, which may be additionally replaced with the settable and/or resettable flip-flop. Further, a flip-flop having fewer fan-outs than the predetermined value used in the previous detection step may be additionally replaced with the settable and/or resettable flip-flop.

In other example embodiments, the scan simulation tool 1170 and the power estimation tool 1190 may be configured to perform the scan simulation and the power estimation on the integrated circuit including the replaced flip-flop to estimate a power consumed during the capture operation of the scan test. If a result of the power estimation during the capture operation satisfies a predetermined criterion (step S1070: YES result), for example, if the power consumed during the capture operation is less than or equal to a predetermined power value, an additional flip-flop will not be replaced. However, if the result of the power estimation during the capture operation does not satisfy a predetermined criterion (step S1070: NO result), for example, if the power consumed during the capture operation is greater than a predetermined power value, the detection of a further flip-flop satisfying the predetermined condition is continued after relaxing the predetermined condition (steps S1090 and S1010), and the replacement of the detected flip-flop is again performed (step S1030).

As described above, the method and the computing system 1100 for designing the integrated circuit according to example embodiments of the inventive concept may replace at least one of the plurality of flip-flops included in the scan chain with the settable flip-flop, the resettable flip-flop, or the settable-and-resettable flip-flop, which is set or reset during the capture operation of the scan test. Accordingly, the peak current during the scan test is reduced and the test coverage of the scan test is increased. Further, the method and the computing system 1100 for designing the integrated circuit according to example embodiments may further perform the scan simulation and/or the power estimation to ensure the reduction of the peak current and/or the increase of the test coverage.

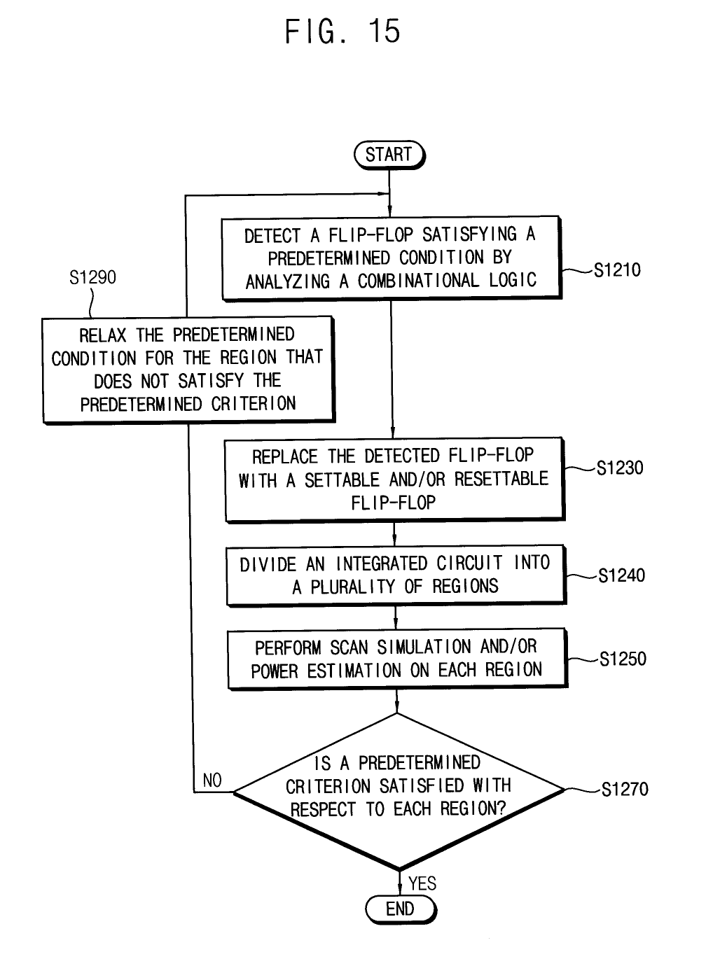

Referring to the embodiment of FIG. 15, in a method of designing an integrated circuit including a combinational logic 310 and a scan chain 330, at least one flip-flop 335 satisfying a predetermined condition may be detected from among a plurality of flip-flops 335 included in the scan chain 330 by analyzing the combinational logic (step S1210). The flip-flop satisfying the predetermined condition is replaced with a settable flip-flop, a resettable flip-flop, or a settable-and-resettable flip-flop (step S1230), according to the inventive concept. Accordingly, a peak current during a capture operation of a scan test may be reduced, and/or testability and a test coverage of the scan test may be improved.

The integrated circuit including the replaced flip-flop may be divided into one or more regions, and a scan simulation and/or a power estimation may be performed on each region (step S1250). Thus, with respect to each region, the number of flip-flops simultaneously, or substantially simultaneously, toggling during the capture operation may be detected, and/or the power consumed during the capture operation may be estimated. If the results of the scan simulation and/or the power estimation with respect to all regions satisfy a predetermine criterion (step S1270: YES result) (e.g., if the number of the flip-flops simultaneously toggling in respective regions is less than or equal to a first predetermined value or if the power consumed during the capture operation in respective regions is less than or equal to a second predetermined value), additional flip-flops will not be replaced. If the result of the scan simulation and/or the power estimation with respect to at least one region does not satisfy the predetermine criterion (step S1270: NO result) (e.g., if the number of the flip-flops simultaneously, or substantially simultaneously, toggling in the region is greater than the first predetermined value or if the power consumed during the capture operation in the region is greater than the second predetermined value), the detection of a further flip-flop satisfying the predetermined condition is continued after relaxing the predetermined condition for the region (steps S1290 and S1210), and the replacement of the detected flip-flop is performed within the region (step S1230). For example, the relaxing of the predetermined condition may include the detection of a flip-flop coupled to an input of a logic cone having a lower logic depth than the predetermined value used in the previous detection step may be additionally replaced with the settable and/or resettable flip-flop. Further, a flip-flop having fewer fan-outs than the predetermined value used in the previous detection step may be additionally replaced with the settable and/or resettable flip-flop.

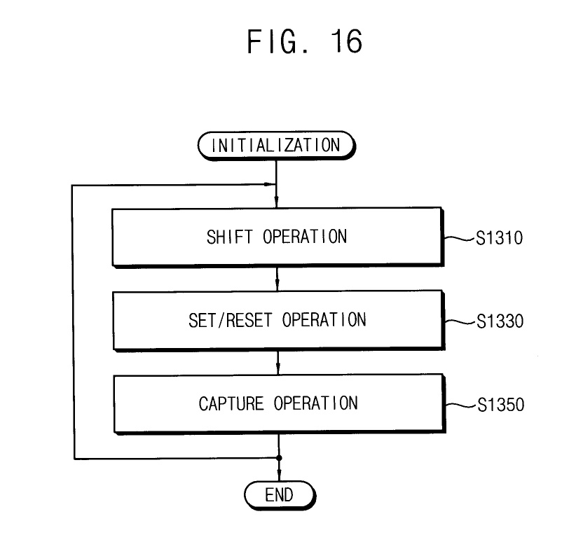

Referring to the embodiment of FIG. 16, an integrated circuit may be initialized to perform a scan test, and a shift-in operation can be performed to sequentially input a predetermined test pattern to a scan chain 330 included in the integrated circuit 300 (step S1310). In some example embodiments, the shift-in operation for the test pattern may be simultaneously, or substantially simultaneously, performed with a shift-out operation for a previous test pattern.

After the shift-in operation, a scan enable signal transitions to a logic low level to perform a capture operation or a capture procedure, and a set/reset operation is performed to set or reset a settable and/or resettable flip-flop according to example embodiments of the inventive concept (step S1330). Further, the capture operation may be performed to store observed values of a combinational logic 310 according to the test pattern in the scan chain 330 (step S1350). In some example embodiments, the set/reset operation is performed before a capture cycle of the capture operation (or the capture procedure). In some example embodiments, in a case where the capture operation includes a plurality of capture cycles, the set/reset operation may be performed between the capture cycles. A shift-out operation can then be performed to sequentially output the observed values stored in the scan chain 330 (step S1310).

As described above, during the scan test of the integrated circuit according to example embodiments, the settable and/or resettable flip-flop is appropriately set or reset during the capture operation of the scan test, which results in the reduction of the peak current and/or the increase of the testability and the test coverage of the scan test.

The inventive concept may be applied to any semiconductor circuit design tool, device, system or method. For example, the inventive concept may be applied to a system-on-chip, a design tool, a device for the system-on-chip or any other suitable semiconductor circuit.

While embodiments in accordance with the inventive concept have been particularly shown and described with reference to exemplary drawings thereof, it will be understood that various changes in form and details may be made therein without departing from the spirit and scope of the following claims, which cover that shown and described with respect to the figures, as well as physical and/or functional equivalents thereof.

What is claimed is:

1. A method of designing or modifying a design of an integrated circuit including a combinational logic and a scan chain, the method comprising:
detecting a flip-flop satisfying a predetermined condition from among a plurality of flip-flops included in the scan chain by analyzing the combinational logic; and
replacing the detected flip-flop with one of a settable flip-flop that is set during a scan test for the integrated circuit, a resettable flip-flop that is reset during the scan test, and a settable-and-resettable flip-flop that is set or reset during the scan test.

2. The method of claim 1, wherein the flip-flop satisfying the predetermined condition includes a flip-flop coupled to an input of a logic cone having a logic depth greater than a first predetermined value, a flip-flop having a number of fan-outs that is greater than a second predetermined value, or a flip-flop coupled to an output of a multiplexer.

3. The method of claim 1, wherein the settable flip-flop is set during a capture operation of the scan test, the resettable flip-flop is reset during a capture operation of the scan test, and the settable-and-resettable flip-flop is set or reset during a capture operation of the scan test.

4. The method of claim 1, wherein detecting a flip-flop satisfying the predetermined condition includes:
detecting at least one logic cone having a logic depth greater than a predetermined value from among a plurality of logic cones included in the combinational logic by analyzing the plurality of logic cones included in the combinational logic; and
detecting a flip-flop coupled to an input of the detected logic cone as the flip-flop satisfying the predetermined condition.

5. The method of claim 4, wherein replacing the detected flip-flop with the settable flip-flop, the resettable flip-flop, or the settable-and-resettable flip-flop includes:
replacing the flip-flop coupled to the input of the detected logic cone with the resettable flip-flop when the detected logic cone is an AND-type logic cone.

6. The method of claim 4, wherein replacing the detected flip-flop with the settable flip-flop, the resettable flip-flop, or the settable-and-resettable flip-flop includes:
replacing the flip-flop coupled to the input of the detected logic cone with the settable flip-flop when the detected logic cone is an OR-type logic cone.

7. The method of claim 4, wherein replacing the detected flip-flop with the settable flip-flop, the resettable flip-flop, or the settable-and-resettable flip-flop includes:
replacing the flip-flop coupled to the input of the detected logic cone with the settable-and-resettable flip-flop.

8. The method of claim 1, wherein detecting the flip-flop satisfying the predetermined condition includes:
detecting a flip-flop having a number of fan-outs that is greater than a predetermined value from among the plurality of flip-flops included in the scan chain.

9. The method of claim 1, wherein detecting the flip-flop satisfying the predetermined condition includes:
detecting a flip-flop coupled to an output of a multiplexer from among the plurality of flip-flops included in the scan chain.

10. The method of claim 1, wherein replacing the detected flip-flop with the settable flip-flop, the resettable flip-flop, or the settable-and-resettable flip-flop includes:
adding an OR gate that performs an OR operation on an output of the detected flip-flop and a set signal to replace the detected flip-flop with the settable flip-flop.

11. The method of claim 1, wherein replacing the detected flip-flop with the settable flip-flop, the resettable flip-flop, or the settable-and-resettable flip-flop includes:
adding a NOR gate that performs a NOR operation on an output of the detected flip-flop and a reset signal to replace the detected flip-flop with the resettable flip-flop.

12. The method of claim 1, wherein replacing the detected flip-flop with the settable flip-flop, the resettable flip-flop, or the settable-and-resettable flip-flop includes:
adding an OR gate that performs an OR operation on an output of the detected flip-flop and a set signal, and a NOR gate that performs a NOR operation on an output of the OR gate and a reset signal to replace the detected flip-flop with the settable-and-resettable flip-flop.

13. The method of claim 1, further comprising:
detecting a number of flip-flops simultaneously toggling during a capture operation of the scan test from among the plurality of flip-flops by performing a scan simulation on the integrated circuit including the replaced flip-flop; and
when the number of the flip-flops substantially simultaneously toggling is greater than a predetermined value, re-performing the steps of detecting and replacing based on a relaxed predetermined condition.

14. The method of claim 1, further comprising:
estimating a power consumed during a capture operation of the scan test by performing a scan simulation and a power estimation on the integrated circuit including the replaced flip-flop; and
when the estimated power is greater than a predetermined value, relaxing the predetermined condition as a relaxed predetermined condition and re-performing the steps of detecting and replacing based on the relaxed predetermined condition.

15. A computing system configured to analyze and modify a design of an integrated circuit including a combinational logic and a scan chain, the computing system comprising:
a memory device into which a design tool for the integrated circuit is loaded; and
a processor configured to execute the design tool loaded into the memory device,
wherein the design tool executed by the processor is configured to detect a flip-flop satisfying a predetermined condition from among a plurality of flip-flops included in the scan chain by analyzing the combinational logic, and to replace the detected flip-flop with a settable flip-flop that is set during a scan test for the integrated circuit, a resettable flip-flop that is reset during the scan test, or a settable-and-resettable flip-flop that is set or reset during the scan test.

16. A method of analyzing and modifying a design of an integrated circuit including a combinational logic divided into regions and a scan chain, the method comprising:
performing an analysis of one of the regions of the combinational logic to determine characteristics of the region;
detecting a flip-flop satisfying a predetermined condition from among a plurality of flip-flops included in the scan chain based on the analysis of the one region of the combinational logic; and
replacing the detected flip-flop with one of a settable flip-flop that is set during a scan test for the integrated circuit, a resettable flip-flop that is reset during the scan test, and a settable-and-resettable flip-flop that is set or reset during the scan test.

17. The method of claim 16, wherein performing the analysis of the one region of the combinational logic includes at least one of determining a logic depth of a logic cone of the combinational logic, performing a scan simulation to determine a number of flip-flops of the scan chain that substantially simultaneously toggle during a capture operation, and/or performing a power estimation to determine an amount of power consumed during the capture operation.

18. The method of claim 16, wherein the flip-flop satisfying the predetermined condition includes a flip-flop coupled to an input of a logic cone having a logic depth greater than a first predetermined value, a flip-flop having a number of fan-outs that is greater than a second predetermined value, or a flip-flop coupled to an output of a multiplexer.

19. The method of claim 16, wherein the settable flip-flop is set during a capture operation of the scan test, the resettable flip-flop is reset during a capture operation of the scan test and the settable-and-resettable flip-flop is set or reset during a capture operation of the scan test.

20. The method of claim 16, wherein detecting a flip-flop satisfying the predetermined condition includes:
detecting at least one logic cone having a logic depth greater than a predetermined value from among a plurality of logic cones included in the combinational logic by analyzing the plurality of logic cones included in the combinational logic; and
detecting a flip-flop coupled to an input of the detected logic cone as the flip-flop satisfying the predetermined condition.
